(19) United States
(12) Patent Application Publication
(10) Pub. No.: US 2012/0223756 A1
(43) Pub. Date: Sep. 6, 2012

(54) Method and System for High Speed, Low Power and Small Flip-Flops

(76) Inventor: Morteza Afghahi, Irvine, CA (US)

(21) Appl. No.: 13/044,002

(22) Filed: Mar. 9, 2011

Related U.S. Application Data
(60) Provisional application No. 61/447,920, filed on Mar. 1, 2011.

(51) Int. Cl. H03K 3/02; H03K 3/3562

(52) U.S. Cl. 327/198; 327/203

(57) ABSTRACT

A master-slave flip-flop may be operable to sense a signal, received by a slave circuit from a master circuit, at a pair of serially coupled NMOS transistors and/or at a pair of serially coupled PMOS transistors in the slave circuit. The flip-flop may generate a corresponding output signal at an output terminal based on the sensing of the signal received by the slave circuit. The flip-flop may receive, in a feedback path of the slave circuit, a SET signal. An inverted version of the SET signal may be received via a gate terminal of a PMOS transistor in the master circuit. The flip-flop may receive, in a feedback path of the master circuit, a RESET signal. The RESET signal may also be received via a gate of a NMOS transistor in the master circuit. The flip-flop may disable an input terminal utilizing the SET signal and/or the RESET signal.

### CROSS-REFERENCE TO RELATED APPLICATIONS

### Incorporation by Reference

This patent application makes reference to, claims priority to, and claims benefit from U.S. Provisional Application Ser. No. 61/447,920, which was filed on Mar. 1, 2011.

The above stated application is hereby incorporated herein by reference in its entirety.

### FIELD OF THE INVENTION

Certain embodiments of the invention relate to electronics circuits. More specifically, certain embodiments of the invention relate to a method and system for high speed, low power and small flip-flops.

### BACKGROUND OF THE INVENTION

In electronics, a flip-flop is a circuit that has two or more stable states and may be used to store information. For example, an output of the flip-flop may be at a state of high voltage representing logic 1 or at a state of low or zero voltage representing logic 0. The flip-flop may be made to change state by signals applied to one or more control inputs and may have one or more outputs. An output of the flip-flop may depend not only on its current input, but also on its previous inputs. For example, when a single input is provided, the flip-flop may change state every time a pulse appears on the input signal. The flip-flop may retain the state after the signal pulses are removed. Another example may be that the flip-flop may have multiple inputs that set a particular state, set an opposite state, or change states, depending on which input is pulsed.

Flip-flops are fundamental building blocks or cells of digital electronics systems used in computers, communications, and many other types of systems. Flip-flops may be implemented using CMOS technology, for example. Flip flops may be constructed from transmission gates, inverters and/or logic gates, for example. Flip-flops may be divided into common types such as the set-reset (RS) flip-flop, the data (D) flip-flop, the toggle (T) flip-flop and/or the JK flip-flop.

Further limitations and disadvantages of conventional and traditional approaches will become apparent to one of skill in the art, through comparison of such systems with the present invention as set forth in the remainder of the present application with reference to the drawings.

### BRIEF SUMMARY OF THE INVENTION

A system and/or method for high speed, low power and small flip-flops, substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram illustrating an exemplary conventional master-slave flip-flop.

FIG. 2A is a block diagram illustrating an exemplary master-slave flip-flop that is operable to provide high speed, low power and small flip-flop, in accordance with an embodiment of the invention.

FIG. 2B is a block diagram illustrating an exemplary input control circuit that is operable to provide high speed, low power and small flip-flop, in accordance with an embodiment of the invention.

FIG. 2C is a block diagram illustrating an exemplary input control circuit that is operable to provide high speed, low power and small flip-flop, in accordance with an embodiment of the invention.

FIG. 3 is a flow chart illustrating exemplary steps for high speed flip-flop, in accordance with an embodiment of the invention.

FIG. 4 is a flow chart illustrating exemplary steps for low power and small set flip-flop, in accordance with an embodiment of the invention.

FIG. 5 is a flow chart illustrating exemplary steps for low power and small reset flip-flop, in accordance with an embodiment of the invention.

### DETAILED DESCRIPTION OF THE INVENTION

Certain embodiments of the invention can be found in a method and system for high speed, low power and small flip-flops. In various embodiments of the invention, a master-slave flip-flop, which may comprise a master circuit, a slave circuit and an input control circuit, may be operable to sense a signal, received by the slave circuit from the master circuit, at a pair of serially coupled NMOS transistors and/or at a pair of serially coupled PMOS transistors in the slave circuit. In this regard, a gate terminal of a first NMOS transistor in the pair of NMOS transistors may be coupled to a terminal at which the signal is received by the slave circuit from the master circuit. A source terminal of the first NMOS transistor may be coupled to ground. A drain terminal of a second NMOS transistor in the pair of NMOS transistors may be coupled to an output terminal of the flip-flop and a gate terminal of the second NMOS transistor may be provided with an inverted version of a clock signal. A gate terminal of a first PMOS transistor in the pair of PMOS transistors may be coupled to the terminal at which the signal is received by the slave circuit from the master circuit. A source terminal of the first PMOS transistor may be coupled to a high voltage. A drain terminal of a second PMOS transistor in the pair of PMOS transistors may be coupled to the output terminal of the flip-flop and a gate terminal of the second PMOS transistor may be provided with the clock signal. The flip-flop may be operable to generate a corresponding output signal at the output terminal of the flip-flop based on the sensing of the signal received by the slave circuit from the master circuit.

In an exemplary embodiment of the invention, the flip-flop may comprise a SET input terminal for generating a high voltage signal at the output terminal. In such an instance, the flip-flop may be operable to receive, in a feedback path of the master circuit, an inverted version of a SET signal from the SET input terminal. The flip-flop may be operable to receive, in a feedback path of the slave circuit, the SET signal from the SET input terminal. In addition, an inverted version of the SET signal from the SET input terminal may be received by the flip-flop via a gate terminal of a third PMOS transistor in the master circuit. In this regard, a drain terminal of the third PMOS transistor may be coupled to a terminal between an output of an on-path transmission gate and an input of an on-path inverter in the master circuit. A source terminal of the third PMOS transistor may be coupled to a high voltage.

The flip-flop may be operable to control, in the input control circuit, enabling and disabling of an input terminal of the flip-flop utilizing a SET signal received from the SET input terminal.

In an exemplary embodiment of the invention, the flip-flop may comprise a RESET input terminal for generating a low voltage signal at the output terminal. In such an instance, the flip-flop may be operable to receive, in a feedback path of the master circuit, a RESET signal from the RESET input terminal. The flip-flop may be operable to receive, in a feedback path of the slave circuit, an inverted version of the RESET signal from the RESET input terminal. In addition, a RESET signal from the RESET input terminal may be received by the flip-flop via a gate of a third NMOS transistor in the master circuit. In this regard, a drain terminal of the third NMOS transistor may be coupled to a terminal between an output of an on-path transmission gate and an input of an on-path inverter in the master circuit. A source terminal of the third NMOS transistor may be coupled to ground.

The flip-flop may be operable to control, in the input control circuit, enabling and disabling of an input terminal of the flip-flop utilizing a RESET signal received from the RESET input terminal.

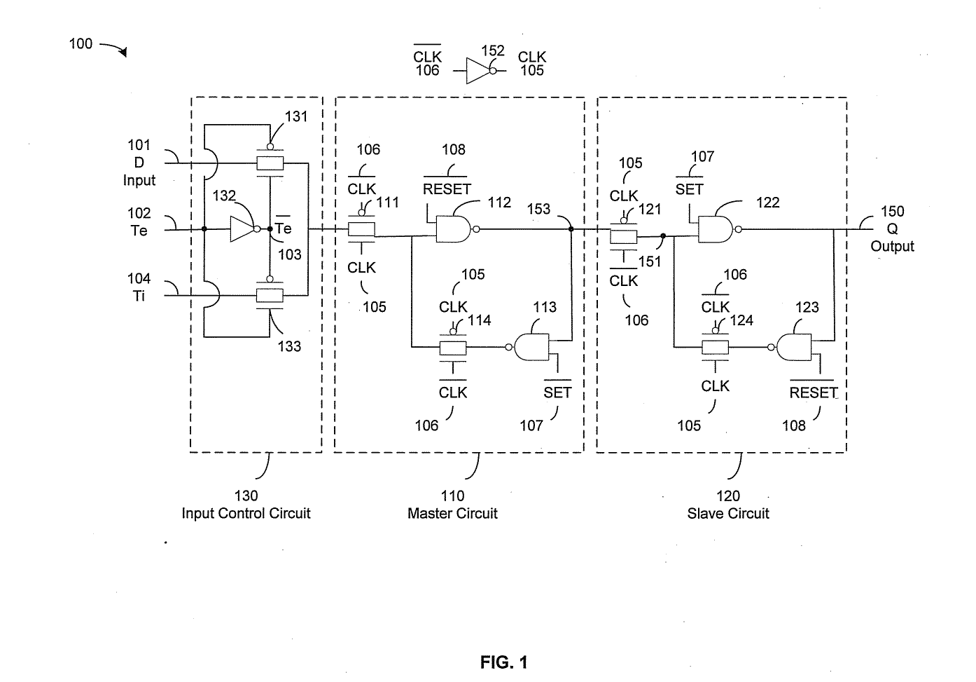

FIG. 1 is a block diagram illustrating an exemplary conventional master-slave flip-flop. Referring to FIG. 1, there is shown a conventional master-slave flip-flop 100. The flip-flop 100 may comprise a master circuit 110, a slave circuit 120 and an input control circuit 130.

The input control circuit 130 may comprise a transmission gate 131, a transmission gate 133 and an inverter 132. The input control circuit 130 may be operable to control receiving input signals from an input terminal D 101 or receiving test signals from a test input terminal Ti 104, based on a signal at a terminal Te 102. While a high voltage signal (logic 1) is applied at the terminal Te 102 during a test or scan operation, the transmission gate 131 is turned off and the transmission gate 133 is turned on. The flip-flop 100 may only receive test signals from the test input terminal Ti 104. While a low or zero voltage signal (logic 0) is applied at the terminal Te 102, the transmission gate 133 is turned off and the transmission gate 131 is turned on. In such an instance, the flip-flop 100 is in normal operation and may receive data input signals from the input terminal D 101.

The master circuit 110 may comprise an on-path NAND gate 112 and a feedback NAND gate 113. The timing of the on-path NAND gate 112 is controlled by a transmission gate 111 and the timing of the feedback NAND gate 113 is controlled by a transmission gate 114. Both the transmission gates 111 and 114 may be turned on or off based on a clock signal CLK 105 and an inverted version of the clock signal C̅L̅K̅ 106. While an inverted version of a SET signal S̅E̅T̅ 107 is at a low or zero voltage (logic 0) and is applied on an input of the NAND gate 113 during a set operation, a low voltage signal (logic 0) may be generated at a terminal 153 of the master circuit 110. A high voltage signal (logic 1) may be generated at the terminal 153 while an inverted version of a RESET signal R̅E̅S̅E̅T̅ 108 is at a low or zero voltage (logic 0) and is applied on an input of the NAND gate 112 during a reset operation.

Similarly, the slave circuit 120 may comprise an on-path NAND gate 122 and a feedback NAND gate 123. The timing of the on-path NAND gate 122 is controlled by a transmission gate 121 and the timing of the feedback NAND gate 123 is controlled by a transmission gate 124. Both the transmission gates 121 and 124 may be turned on or off based on the clock signal CLK 105 and the inverted version of the clock signal C̅L̅K̅ 106. While an inverted version of a SET signal S̅E̅T̅ 107 is at a low or zero voltage (logic 0) and is applied on an input of the NAND gate 122 during a set operation, a high voltage signal (logic 1) may be generated at an output terminal Q 150 of the flip-flop 100. A low voltage signal (logic 0) may be generated at the output terminal Q 150 of the flip-flop 100 while the inverted version of the RESET signal R̅E̅S̅E̅T̅ 108 is at a low or zero voltage (logic 0) and is applied on an input of the NAND gate 123 during a reset operation. The slave circuit 120 in this master-slave series in the flip-flop 100 may only change in response to a change in the master circuit 110.

In normal operation, in order for the output terminal Q 150 to change from a state of low voltage (logic 0) to a state of high voltage (logic 1), a terminal 151 between the transmission gate 121 and the NAND gate 122 may need to change to a state of low voltage. The terminal 151 may change to a state of low voltage as soon as the transmission gate 121 is turned on and a low voltage signal may pass primarily through a NMOS transistor in the transmission gate 121. The transmission gate 121 is turned on when the signal C̅L̅K̅ 106 changes to a high voltage signal and the signal CLK 105 changes to a low voltage signal. In order for the output terminal Q 150 to change from a state of high voltage to a state of low voltage, the terminal 151 may need to change to a state of high voltage. The terminal 151 may change to a state of high voltage as soon as the transmission gate 121 is turned on and a high voltage signal may pass primarily through a PMOS transistor in the transmission gate 121. In general, the PMOS transistor is slower than the NMOS transistor. In addition, there may be a delay between the signal CLK 105 and the signal C̅L̅K̅ 106 due to an inversion operation such as, for example, due to the inversion operation of an inverter 152. In this regard, the high voltage signal passing through the PMOS transistor may be delayed and/or slower with respect to the low voltage signal passing through the NMOS transistor in the transmission gate 121. Accordingly, a change from a state of high voltage (logic 1) to a state of low voltage (logic 0) at the output terminal Q 150 of this conventional flip-flop 100 may be slower than a change from a state of low voltage (logic 0) to a state of high voltage (logic 1) at the output terminal Q 150, for example.

The on-path NAND gate 112 which may receive the S̅E̅T̅ signal 107 and the on-path NAND gate 112 which may receive the R̅E̅S̅E̅T̅ signal 108 are both in a direct path from the input terminal D 101 to the output terminal Q 150. A NAND gate is in general slower, bigger and more power-consuming than an inverter. In particular, the NAND gate 122 in the direct path to the output terminal Q 150 may be scaled up in size to drive high loads coupled to the output terminal Q 150, for example. Scaling up a NAND gate is much more costly than scaling up an inverter. The scaling-up of the NAND gate 122 in the direct path to the output terminal Q 150 may also require to scale up the transmission gate 121, and may in turn result in more power consumption and bigger size of the conventional flip-flop 100.

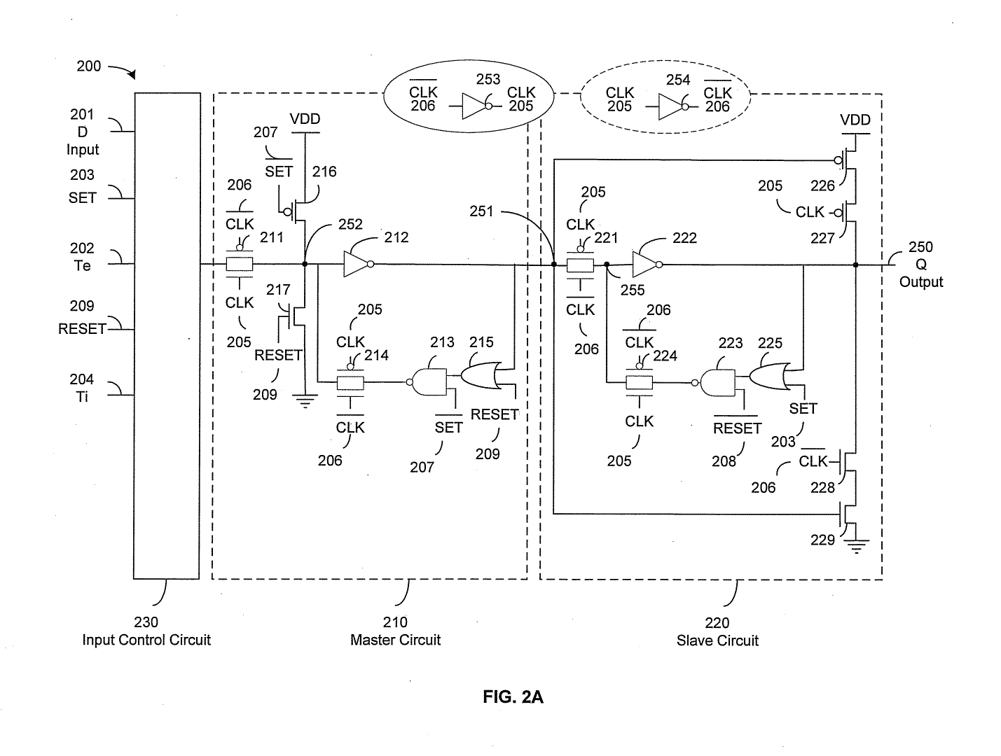

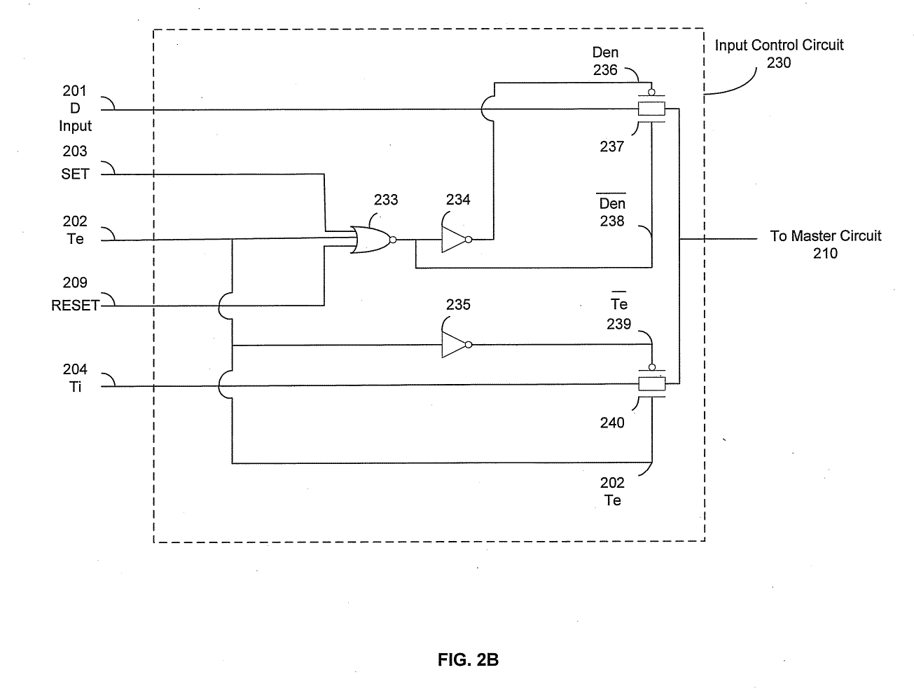

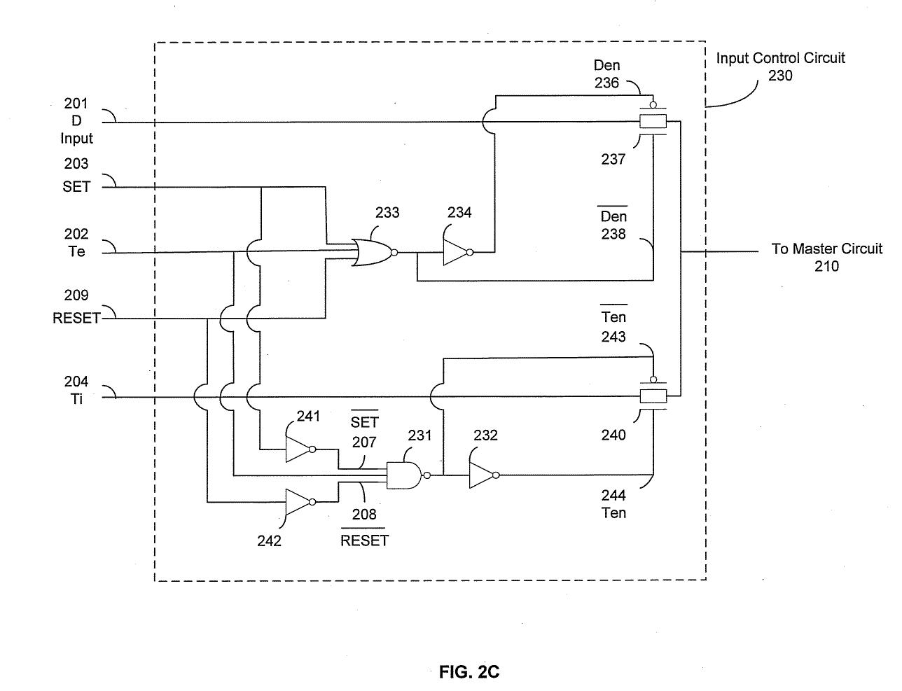

FIG. 2A is a block diagram illustrating an exemplary master-slave flip-flop that is operable to provide high speed, low power and small flip-flop, in accordance with an embodiment of the invention. Referring to FIG. 2A, there is shown a master-slave flip-flop 200. The flip-flop 200 may comprise a master circuit 210, a slave circuit 220 and an input control circuit 230.

The input control circuit 230 may comprise suitable logic, circuitry, interfaces and/or code that may be operable to control receiving input signals from an input terminal D 201 or receiving test signals from a test input terminal Ti 204, based on a signal at a terminal Te 202. In an exemplary embodiment of the invention, a SET signal at a SET input terminal 203 and/or a RESET signal at a RESET input terminal 209 may be utilized by the input control circuit 230 to control enabling and disabling of the input terminal D 201 and/or the test input terminal Ti 204. Additional exemplary details of the input control circuit 230 may be described below with respect to FIG. 2B and FIG. 2C.

The master circuit 210 may comprise an on-path inverter 212, a feedback NAND gate 213, a feedback OR gate 215, a PMOS transistor 216 and a NMOS transistor 217. The timing of the on-path inverter 212 is controlled by a transmission gate 211 and the timing of the feedback NAND gate 213 and the feedback OR gate 215 is controlled by a transmission gate 214. Both the transmission gates 211 and 214 may be turned on or off based on a clock signal CLK 205 and an inverted version of the clock signal C̅L̅K̅ 206. The master circuit 210 does not comprise an on-path NAND gate so as to reduce size and power consumption of the flip-flop 200.

During a set operation, an inverted version of a SET signal S̅E̅T̅ at a terminal 207 is at a low or zero voltage (logic 0) and may be applied on an input of the NAND gate 213. In an exemplary embodiment of the invention, the low voltage S̅E̅T̅ signal at the terminal 207 may also be applied on a gate terminal of the PMOS transistor 216 to turn on the PMOS transistor 216. A high voltage SET signal at the SET input terminal 203 may also be applied to the input control circuit 230 to disable the input terminal D 201. Accordingly, a high voltage signal (logic 1) may be generated at a terminal 252 and a low voltage signal (logic 0) may then be generated at a terminal 251.

During a reset operation, the RESET signal at the RESET input terminal 209 is at a high voltage (logic 1). In an exemplary embodiment of the invention, this RESET signal at the RESET input terminal 209 may be applied on an input of the OR gate 215. The high voltage RESET signal at the RESET input terminal 209 may also be applied on a gate terminal of the NMOS transistor 217 to turn on the NMOS transistor 217. A high voltage RESET signal at the RESET input terminal 209 may also be applied to the input control circuit 230 to disable the input terminal D 201. Accordingly, a low voltage signal (logic 0) may be generated at the terminal 252 and a high voltage signal (logic 1) may then be generated at the terminal 251.

The slave circuit 220 may comprise an on-path inverter 222, a feedback NAND gate 223, a feedback OR gate 225, a pair of serially coupled PMOS transistors 226, 227 and a pair of serially coupled NMOS transistors 228, 229. The timing of the on-path inverter 222 is controlled by a transmission gate 221 and the timing of the feedback NAND gate 223 and the feedback OR gate 225 is controlled by a transmission gate 224. Both the transmission gates 221 and 224 may be turned on or off based on the clock signal CLK 205 and the inverted version of the clock signal C̅L̅K̅ 206. The timing of the pair of PMOS transistors 226, 227 is controlled by the signal CLK 205, which is applied on a gate terminal of the PMOS transistor 227. The timing of the pair of NMOS transistors 228, 229 is controlled by the signal C̅L̅K̅ 206, which is applied on a gate terminal of the NMOS transistor 228. The slave circuit 220 does not comprise an on-path NAND gate so as to reduce size and power consumption of the flip-flop 200.

In order for an output terminal Q 150 to change from a state of low voltage (logic 0) to a state of high voltage (logic 1), a terminal 255 between the transmission gate 221 and the inverter 222 may need to change to a state of low voltage. The terminal 155 may change to a state of low voltage as soon as the transmission gate 221 is turned on and a low voltage signal may pass primarily through a NMOS transistor in the transmission gate 221. The transmission gate 221 is turned on when the signal C̅L̅K̅ 206 changes to a high voltage signal and the signal CLK 205 changes to a low voltage signal. In order for the output terminal Q 250 to change from a state of high voltage to a state of low voltage, the terminal 255 may need to change to a state of high voltage. The terminal 255 may change to a state of high voltage as soon as the transmission gate 221 is turned on and a high voltage signal may pass primarily through a PMOS transistor in the transmission gate 221. In general, the PMOS transistor is slower than the NMOS transistor. In addition, in instances when the signal CLK 205 is generated from the signal C̅L̅K̅ 206 via an inversion operation of an inverter 253, the signal CLK 205 may be delayed with respect to the signal C̅L̅K̅ 206 due to the inversion operation. In such instances, a change from a state of low voltage (logic 0) to a state of high voltage (logic 1) at the terminal 255 may be slower than a change from a state of high voltage (logic 1) to a state of low voltage (logic 0) at the terminal 255.

In other instances, the signal C̅L̅K̅ 206 may be generated from the signal CLK 205 via an inversion operation of an inverter 254. The signal C̅L̅K̅ 206 may be delayed with respect to the signal CLK 205 due to the inversion operation. In this regard, a change from a state of high voltage (logic 1) to a state of low voltage (logic 0) at the terminal 255 may be slower than a change from a state of low voltage (logic 0) to a state of high voltage (logic 1) at the terminal 255.

In an embodiment of the invention, a high voltage signal (logic 1) at the terminal 251 (an input of the transmission gate 221) may be sensed by a gate terminal of the NMOS transistor 229 as soon as the signal C̅L̅K̅ 206 changes to a high voltage signal. Therefore, the pair of NMOS transistors 228, 229 may be turned on and a low voltage signal (logic 0) may be generated at the output terminal Q 250 as soon as the signal C̅L̅K̅ 206 changes to a high voltage signal. In this regard, a change from a high voltage signal (logic 1) to a low voltage signal (logic 0) at the output terminal Q 250 through the pair of NMOS transistors 228, 229 may be faster than a change from a high voltage signal (logic 1) to a low voltage signal (logic 0) at the output terminal Q 250 through the transmission gate 221. The delay of the change from a high voltage signal to a low voltage signal at the output terminal Q 250 through the transmission gate 221 may be due to, for example, the high voltage signal passing through the PMOS transistor in the transmission gate 221 and/or the inversion operation of the inverter 253.

In another embodiment of the invention, a low voltage signal (logic 0) at the terminal 251 (the input of the transmission gate 221) may be sensed by a gate of the PMOS transistor 226 as soon as the signal CLK 205 changes to a low voltage signal. Therefore, the pair of PMOS transistors 226, 227 may be turned on and a high voltage signal (logic 1) may be generated at the output terminal Q 250 as soon as the signal CLK 205 changes to a low voltage signal. In this regard, a change from a low voltage signal (logic 0) to a high voltage signal (logic 1) at the output terminal Q 250 through the pair of PMOS transistors 226, 227 may be faster than a change from a low voltage signal (logic 0) to a high voltage signal (logic 1) at the output terminal Q 250 through the transmission gate 221. The delay of the change from a low voltage signal to a high voltage signal at the output terminal Q 250 through the transmission gate 221 may be due to, for example, the inversion operation of the inverter 254.

During a set operation, the SET signal at the SET input terminal 203 is at a high voltage (logic 1). In an exemplary embodiment of the invention, this high voltage SET signal at the SET input terminal 203 may be applied on an input of the OR gate 225. Together with the set operation in the master circuit 210, a high voltage signal (logic 1) may be generated at the output terminal Q 250.

During a reset operation, an inverted version of the RESET signal R̅E̅S̅E̅T̅ at a terminal 208 is at a low or zero voltage (logic 0) and may be applied on an input of the NAND gate 223. Together with the reset operation in the master circuit 210, a low voltage signal (logic 0) may be generated at the output terminal Q 250.

In operation, the timing of the pair of PMOS transistors 226, 227 is controlled by the signal CLK 205, which is applied on the gate terminal of the PMOS transistor 227. The timing of the pair of NMOS transistors 228, 229 is controlled by the signal C̅L̅K̅ 206, which is applied on the gate terminal of the NMOS transistor 228. A high voltage signal (logic 1) at the terminal 251 between the master circuit 210 and the slave circuit 220 may be sensed by the gate terminal of the NMOS transistor 229 as soon as the signal C̅L̅K̅ 206 changes to a high voltage signal. In this regard, the pair of NMOS transistors 228, 229 may be turned on and a low voltage signal (logic 0) may be generated at the output terminal Q 250 as soon as the signal C̅L̅K̅ 206 changes to a high voltage signal.

A low voltage signal (logic 0) at the terminal 251 between the master circuit 210 and the slave circuit 220 may be sensed by the gate of the PMOS transistor 226 as soon as the signal CLK 205 changes to a low voltage signal. In this regard, the pair of PMOS transistors 226, 227 may be turned on and a high voltage signal (logic 1) may be generated at the output terminal Q 250 as soon as the signal CLK 205 changes to a low voltage signal.

During a set operation, the SET signal at the SET input terminal 203 is at a high voltage (logic 1) and may be applied on the input of the OR gate 225 in the slave circuit 220. An inverted version of a SET signal S̅E̅T̅ at the terminal 207 is at a low or zero voltage (logic 0) and may be applied on the input of the NAND gate 213 in the master circuit 210. When the signal CLK 205 changes to a low voltage signal, the transmission gate 224 in a feedback path of the slave circuit 220 is turned off. However, there may be a time interval during which the transmission gate 214 in a feedback path of the master circuit 210 may not be turned on yet due to, for example, a delay associated with the operation of the transmission gate 214. In this regard, the low voltage S̅E̅T̅ signal at the terminal 207 may be applied on the gate terminal of the PMOS transistor 216 in the master circuit 210. The PMOS transistor 216 may be turned on as soon as the low voltage S̅E̅T̅ signal is sensed by the gate terminal of the PMOS transistor 216. A high voltage SET signal at the SET input terminal 203 may also be applied to the input control circuit 230 to disable the input terminal D 201. The input terminal D 201 is disabled in order to avoid passing an input signal through the terminal 252. Accordingly, a high voltage signal (logic 1) may be generated at the terminal 252 and in turn a high voltage signal (logic 1) may be generated at the output terminal Q 250.

During a reset operation, an inverted version of the RESET signal R̅E̅S̅E̅T̅ at a terminal 208 is at a low or zero voltage (logic 0) and may be applied on the input of the NAND gate 223 in the slave circuit 220. The RESET signal at the RESET input terminal 209 is at a high voltage (logic 1) and may be applied on the input of the OR gate 215 in the master circuit 210. When the signal CLK 205 changes to a low voltage signal, the transmission gate 224 in the feedback path of the slave circuit 220 is turned off. However, there may be a time interval during which the transmission gate 214 in the feedback path of the master circuit 210 may not be turned on yet due to, for example, a delay associated with the operation of the transmission gate 214. In this regard, the high voltage RESET signal at the RESET input terminal 209 may also be applied on the gate terminal of the NMOS transistor 217 in the master circuit 210. The NMOS transistor 217 may be turned on as soon as the high voltage RESET signal is sensed by the gate terminal of the NMOS transistor 217. A high voltage RESET signal at the RESET input terminal 209 may also be applied to the input control circuit 230 to disable the input terminal D 201. The input terminal D 201 is disabled in order to avoid passing an input signal through the terminal 252. Accordingly, a low voltage signal (logic 0) may be generated at the terminal 252 and in turn a low voltage signal (logic 0) may be generated at the output terminal Q 250.

In the exemplary embodiment of the invention illustrated in FIG. 2A, the flip-flop 200 which comprises the input terminal D 201, the SET input terminal 203, the RESET input terminal 209, the test input terminal Ti 204 and the terminal Te 202 is shown. Notwithstanding, the invention is not so limited. Accordingly, other input configurations of the flip-flop 200 may be illustrated without departing from the spirit and scope of various embodiments of the invention. For example, the flip-flop 200 which does not comprise the test input terminal Ti 204 and the input terminal Te 202 for a test or scan operation may be illustrated. The flip-flop 200 which does not comprise the SET input terminal 203 and/or the RESET input terminal 209 may be illustrated, for example. In instances when the flip-flop 200 is a SET flip-flop which does not comprise the RESET input terminal 209, the OR gate 215 in the master circuit 210 and the NAND gate 223 in the slave circuit 220 may be removed. The OR gate 225 in the slave circuit 220 may be replaced by a NOR gate and the NMOS transistor 217 in the master circuit 210 may be removed. In instances when the flip-flop 200 is a RESET flip-flop which does not comprise the SET input terminal 203, the NAND gate 213 in the master circuit 210 and the OR gate 225 in the slave circuit 220 may be removed. The OR gate 215 in the master circuit 210 may be replaced by a NOR gate and the PMOS transistor 216 in the master circuit 210 may be removed. In instances when the flip-flop 200 is a D flip-flop which does not comprise the SET input terminal 203 and the RESET input terminal 209, the OR gate 215 in the master circuit 210 and the OR gate 225 in the slave circuit 220 may be removed. The NAND gate 213 in the master circuit 210 may be replaced by an inverter and the NAND gate 223 in the slave circuit 220 may be replaced by an inverter. The PMOS transistor 216 and the NMOS transistor 217 in the master circuit 210 may be removed.

FIG. 2B is a block diagram illustrating an exemplary input control circuit that is operable to provide high speed, low power and small flip-flop, in accordance with an embodiment of the invention. Referring to FIG. 2B, there is shown an input control circuit 230. The input control circuit 230 may comprise a transmission gate 237, a transmission gate 240, a NOR gate 233, an inverter 234 and an inverter 235. The input control circuit 230 may be coupled to a master circuit 210 in a flip-flop 200.

In operation, the input control circuit 230 may be operable to control receiving input signals from an input terminal D 201 or receiving test signals from a test input terminal Ti 204, based on a signal at a terminal Te 202. While a high voltage signal (logic 1) is applied on the terminal Te 202 during a test or scan operation, the transmission gate 237 is turned off and the transmission gate 240 is turned on. The master circuit 210 in the flip-flop 200 may only receive test signals from the test input terminal Ti 204. While a low or zero voltage signal (logic 0) is applied on the terminal Te 202, the transmission gate 240 is turned off and the transmission gate 237 is turned on. In such an instance, the master circuit 210 may receive data input signals from the input terminal D 201 and the flip-flop 200 is in normal operation.

During a set operation of the flip-flop 200, a SET signal at a SET input terminal 203 is at a high voltage (logic 1) and may be applied on an input of the NOR gate 233. The transmission gate 237 is turned off. In this regard, the input terminal D 201 may be disabled without passing input signals to the master circuit 210 during the set operation. Similarly, during a reset operation of the flip-flop 200, a RESET signal at a RESET input terminal 209 is at a high voltage (logic 1) and may be applied on an input of the NOR gate 233. The transmission gate 237 is turned off. In this regard, the input terminal D 201 may be disabled without passing input signals to the master circuit 210 during the reset operation.

The transmission gate 237 may be turned on or turned off based on the signals received from the terminal Te 202, the set input terminal 203 and/or the reset input terminal 209. The transmission gate 240 may be turned on or turned off only based on the signals received from the terminal Te 202.

FIG. 2C is a block diagram illustrating an exemplary input control circuit that is operable to provide high speed, low power and small flip-flop, in accordance with an embodiment of the invention. Referring to FIG. 2C, there is shown an input control circuit 230. The input control circuit 230 may comprise a transmission gate 237, a transmission gate 240, a NOR gate 233, an inverter 234, an inverter 241, an inverter 242, an NAND gate 231 and an inverter 232. The input control circuit 230 may be coupled to a master circuit 210 in a flip-flop 200.

In operation, the input control circuit 230 may be operable to control receiving input signals from an input terminal D 201 or receiving test signals from a test input terminal Ti 204, based on a signal at a terminal Te 202. While a high voltage signal (logic 1) is applied on the terminal Te 202 during, for example, a test or scan operation, the transmission gate 237 is turned off and the transmission gate 240 is turned on. The master circuit 210 in the flip-flop 200 may only receive test signals from the test input terminal Ti 204. While a low or zero voltage signal (logic 0) is applied on the terminal Te 202, the transmission gate 240 is turned off and the transmission gate 237 is turned on. In such an instance, the master circuit 210 may receive data input signals from the input terminal D 201 and the flip-flop 200 is in normal operation.

In instances when a low or zero voltage signal (logic 0) is applied on the terminal Te 202, the master circuit 210 in the flip-flop 200 may receive input signals from the input terminal D 201 through the transmission gate 237. However, during a set operation of the flip-flop 200, a SET signal at a SET input terminal 203 is at a high voltage (logic 1) and may be applied on an input of the NOR gate 233. The transmission gate 237 is turned off during the set operation. In this regard, the input terminal D 201 may be disabled without passing input signals to the master circuit 210 during the set operation. Similarly, during a reset operation of the flip-flop 200, a RESET signal at a RESET input terminal 209 is at a high voltage (logic 1) and may be applied on an input of the NOR gate 233. The transmission gate 237 is turned off during the reset operation. In this regard, the input terminal D 201 may be disabled without passing input signals to the master circuit 210 during the reset operation.

In instances when a high voltage signal (logic 1) is applied on the terminal Te 202, the master circuit 210 in the flip-flop 200 may receive test signals from the test input terminal Ti 204 through the transmission gate 240. However, during a set, operation of the flip-flop 200, a SET signal at a SET input terminal 203 is at a high voltage (logic 1). An inverted version of the SET signal S̅E̅T̅ at a terminal 207 is at a low or zero voltage (logic 0) and may be applied on an input of the NAND gate 231. Accordingly, the transmission gate 240 is turned off during the set operation. In this regard, the test input terminal Ti 204 may be disabled without passing test signals to the master circuit 210 during the set operation. Similarly, during a reset operation of the flip-flop 200, a RESET signal at a RESET input terminal 209 is at a high voltage (logic 1). An inverted version of the RESET signal R̅E̅S̅E̅T̅ at a terminal 208 is at a low or zero voltage (logic 0) and may be applied on an input of the NAND gate 231. Accordingly, the transmission gate 240 is turned off during the reset operation. In this regard, the test input terminal Ti 204 may be disabled without passing test signals to the master circuit 210 during the reset operation.

The transmission gate 237 may be turned on or turned off based on the signals received from the terminal Te 202, the set input terminal 203 and/or the reset input terminal 209. Similarly, the transmission gate 240 may be turned on or turned off based on the signals received from the terminal Te 202, the set input terminal 203 and/or the reset input terminal 209.

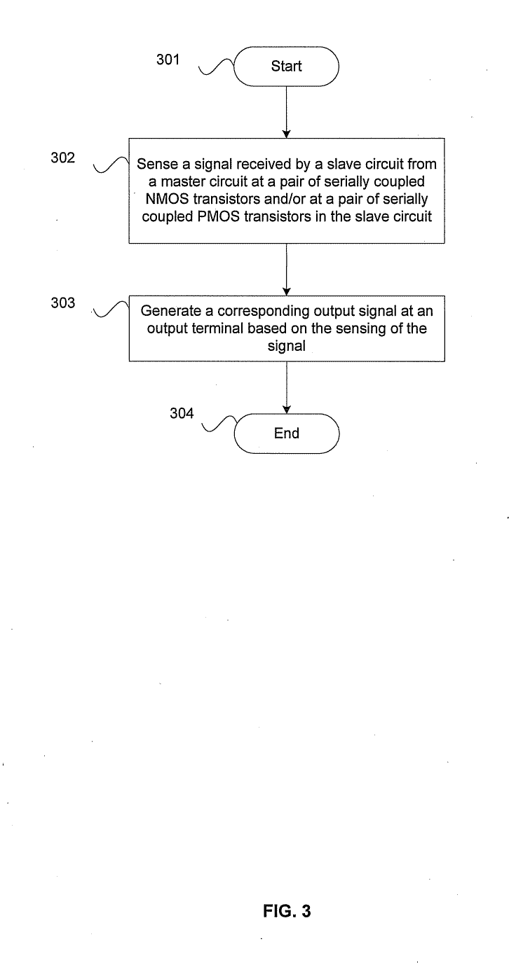

FIG. 3 is a flow chart illustrating exemplary steps for high speed flip-flop, in accordance with an embodiment of the invention. Referring to FIG. 3, the exemplary steps start at step 301. In step 302, the master-slave flip-flop 200 may be operable to sense a signal received by a slave circuit 220 from a master circuit 210 at a pair of serially coupled NMOS transistors 228, 229 and/or at a pair of serially coupled PMOS transistors 226, 227 in the slave circuit 220. In step 303, the master-slave flip-flop 200 may be operable to generate a corresponding output signal at an output terminal Q 250 based on the sensing of the signal. The exemplary steps may proceed to the end step 304.

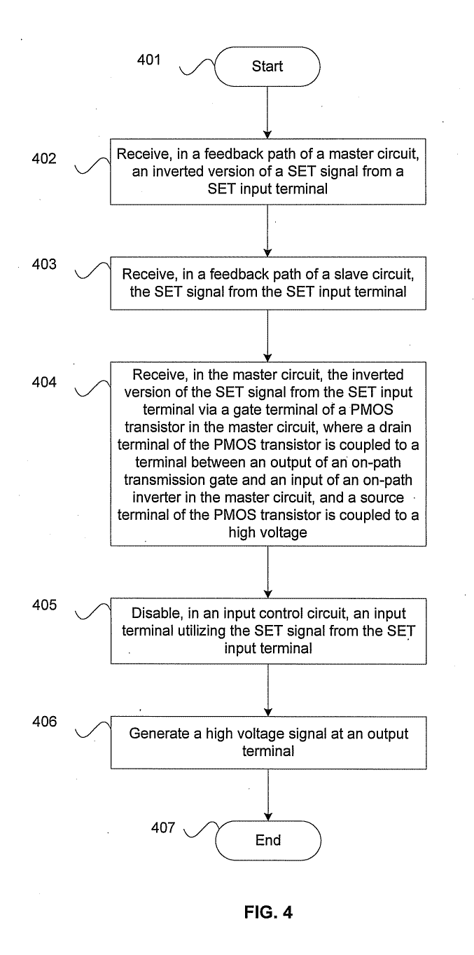

FIG. 4 is a flow chart illustrating exemplary steps for low power and small set flip-flop, in accordance with an embodiment of the invention. Referring to FIG. 4, the exemplary steps start at step 401. In step 402, the master-slave flip-flop 200 may be operable to receive, in a feedback path of a master circuit 210, an inverted version of a SET signal from a SET input terminal 203. In step 403, the SET signal from the SET input terminal 203 may be received, in a feedback path of a slave circuit 220, by the flip-flop 200. In step 404, the flip-flop 200 may be operable to receive, in the master circuit 210, the inverted version of the SET signal from the SET input terminal 203 via a gate terminal of a PMOS transistor 216 in the master circuit 210. A drain terminal of the PMOS transistor 216 may be coupled to a terminal 252 between an output of an on-path transmission gate 211 and an input of an on-path inverter 212, and a source terminal of the PMOS transistor 216 may be coupled to a high voltage. In step 405, an input terminal D 201 may be disabled, in an input control circuit 230, by the flip-flop 200 utilizing the SET signal from the SET input terminal 203. In step 406, a high voltage signal may be generated at an output terminal Q 250 by the flip-flop 200. The exemplary steps may proceed to the end step 407.

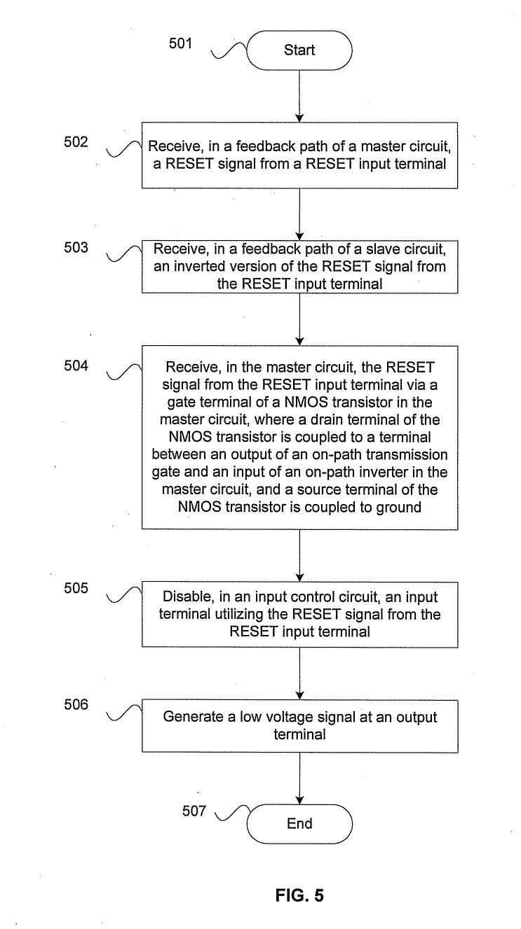

FIG. 5 is a flow chart illustrating exemplary steps for low power and small reset flip-flop, in accordance with an embodiment of the invention. Referring to FIG. 5, the exemplary steps start at step 501. In step 502, the master-slave flip-flop 200 may be operable to receive, in a feedback path of a master circuit 210, a RESET signal from a RESET input terminal 209. In step 503, an inverted version of the RESET signal from the RESET input terminal 209 may be received, in a feedback path of a slave circuit 220, by the flip-flop 200. In step 504, the flip-flop 200 may be operable to receive, in the master circuit 210, the RESET signal from the RESET input terminal 209 via a gate terminal of a NMOS transistor 217 in the master circuit 210. A drain terminal of the NMOS transistor 217 may be coupled to a terminal 252 between an output of an on-path transmission gate 211 and an input of an on-path inverter 212, and a source terminal of the NMOS transistor 217 may be coupled to ground. In step 505, an input terminal D 201 may be disabled, in an input control circuit 230, by the flip-flop 200 utilizing the RESET signal from the RESET input terminal 209. In step 506, a low voltage signal may be generated at an output terminal Q 250 by the flip-flop 200. The exemplary steps may proceed to the end step 507.

In various embodiments of the invention, a master-slave flip-flop 200, which may comprise a master circuit 210, a slave circuit 220 and an input control circuit 230, may be operable to sense a signal, received by the slave circuit 220 from the master circuit 210, at a pair of serially coupled NMOS transistors 228, 229 and/or at a pair of serially coupled PMOS transistors 226, 227 in the slave circuit 220. In this regard, a gate terminal of a first NMOS transistor 229 in the pair of NMOS transistors 228, 229 may be coupled to a terminal 251 at which the signal is received by the slave circuit 220 from the master circuit 210. A source terminal of the first NMOS transistor 229 may be coupled to ground. A drain terminal of a second NMOS transistor 228 in the pair of NMOS transistors 228, 229 may be coupled to an output terminal Q 250 of the flip-flop 200 and a gate terminal of the second NMOS transistor 228 may be provided with an inverted version of a clock signal C̅L̅K̅ 206. A gate terminal of a first PMOS transistor 226 in the pair of PMOS transistors 226, 227 may be coupled to the terminal 251 at which the signal is received by the slave circuit 220 from the master circuit 210. A source terminal of the first PMOS transistor 226 may be coupled to a high voltage. A drain terminal of a second PMOS transistor 227 in the pair of PMOS transistors 226, 227 may be coupled to the output terminal Q 250 of the flip-flop 200 and a gate terminal of the second PMOS transistor 227 may be provided with the clock signal CLK 205. The flip-flop 200 may be operable to generate a corresponding output signal at the output terminal Q 250 of the flip-flop 200 based on the sensing of the signal received at the terminal 251 by the slave circuit 220 from the master circuit 210.

In an exemplary embodiment of the invention, the flip-flop 200 may comprise a SET input terminal 203 for generating a high voltage signal at the output terminal Q 250. In such an instance, the flip-flop 200 may be operable to receive, in a feedback path of the master circuit 210, an inverted version of a SET signal from the SET input terminal 203. The flip-flop 200 may be operable to receive, in a feedback path of the slave circuit 220, the SET signal from the SET input terminal 203. In addition, an inverted version of the SET signal from the SET input terminal 203 may be received by the flip-flop 200 via a gate terminal of a third PMOS transistor 216 in the master circuit 210. In this regard, a drain terminal of the third PMOS transistor 216 may be coupled to a terminal 252 between an output of an on-path transmission gate 211 and an input of an on-path inverter 212 in the master circuit 210. A source terminal of the third PMOS transistor 216 may be coupled to a high voltage.

The flip-flop 200 may be operable to control, in the input control circuit 230, enabling and disabling of an input terminal D 201 of the flip-flop 200 utilizing a SET signal received from the SET input terminal 203.

In an exemplary embodiment of the invention, the flip-flop 200 may comprise a RESET input terminal 209 for generating a low voltage signal at the output terminal Q 250. In such an instance, the flip-flop 200 may be operable to receive, in a feedback path of the master circuit 210, a RESET signal from the RESET input terminal 209. The flip-flop 200 may be operable to receive, in a feedback path of the slave circuit 220, an inverted version of the RESET signal from the RESET input terminal 209. In addition, a RESET signal from the RESET input terminal 209 may be received by the flip-flop 200 via a gate of a third NMOS transistor 217 in the master circuit 210. In this regard, a drain terminal of the third NMOS transistor 217 may be coupled to a terminal 252 between an output of an on-path transmission gate 211 and an input of an on-path inverter 212 in the master circuit 210. A source terminal of the third NMOS transistor 217 may be coupled to ground.

The flip-flop 200 may be operable to control, in the input control circuit 230, enabling and disabling of an input terminal D 201 of the flip-flop 200 utilizing a RESET signal received from the RESET input terminal 209.

Other embodiments of the invention may provide a non-transitory computer readable medium and/or storage medium, and/or a non-transitory machine readable medium and/or storage medium, having stored thereon, a machine code and/or a computer program having at least one code section executable by a machine and/or a computer, thereby causing the machine and/or computer to perform the steps as described herein for high speed, low power and small flip-flops.

Accordingly, the present invention may be realized in hardware, software, or a combination of hardware and software. The present invention may be realized in a centralized fashion in at least one computer system or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for flip-flop circuitry, the method comprising:
in a master-slave flip-flop comprising a master circuit, a slave circuit and an input control circuit:
sensing a signal received by said slave circuit from said master circuit at a pair of serially coupled NMOS transistors and/or at a pair of serially coupled PMOS transistors in said slave circuit, wherein:
a gate terminal of a first NMOS transistor in said pair of NMOS transistors is coupled to a terminal at which said signal is received by said slave circuit from said master circuit;
a drain terminal of a second NMOS transistor in said pair of NMOS transistors is coupled to an output terminal of said flip-flop and a gate terminal of said second NMOS transistor is provided with an inverted version of a clock signal;
a gate terminal of a first PMOS transistor in said pair of PMOS transistors is coupled to said terminal at which said signal is received by said slave circuit from said master circuit; and
a drain terminal of a second PMOS transistor in said pair of PMOS transistors is coupled to said output terminal and a gate of said second PMOS transistor is provided with said clock signal; and
generating a corresponding output signal at said output terminal based on said sensing of said signal.

2. The method according to claim 1, wherein a source terminal of said first NMOS transistor is coupled to ground and a source terminal of said first PMOS transistor is coupled to a high voltage.

3. The method according to claim 1, wherein said flip-flop comprises a SET input terminal for generating a high voltage signal at said output terminal.

4. The method according to claim 3, comprising:
receiving, in a feedback path of said master circuit, an inverted version of a SET signal from said SET input terminal; and
receiving, in a feedback path of said slave circuit, said SET signal from said SET input terminal.

5. The method according to claim 3, comprising receiving, in said master circuit, an inverted version of a SET signal from said SET input terminal via a gate terminal of a third PMOS transistor in said master circuit, wherein:
a drain terminal of said third PMOS transistor is coupled to a terminal between an output of an on-path transmission gate and an input of an on-path inverter in said master circuit; and
a source terminal of said third PMOS transistor is coupled to a high voltage.

6. The method according to claim 3, comprising controlling, in said input control circuit, enabling and disabling of an input terminal of said flip-flop utilizing a SET signal received from said SET input terminal.

7. The method according to claim 1, wherein said flip-flop comprises a RESET input terminal for generating a low voltage signal at said output terminal.

8. The method according to claim 7, comprising:
receiving, in a feedback path of said master circuit, a RESET signal from said RESET input terminal; and
receiving, in a feedback path of said slave circuit, an inverted version of said RESET signal from said RESET input terminal.

9. The method according to claim 7, comprising receiving, in said master circuit, a RESET signal from said RESET input terminal via a gate terminal of a third NMOS transistor in said master circuit, wherein:
a drain terminal of said third NMOS transistor is coupled to a terminal between an output of an on-path transmission gate and an input of an on-path inverter in said master circuit; and
a source terminal of said third NMOS transistor is coupled to ground.

10. The method according to claim 7, comprising controlling, in said input control circuit, enabling and disabling of an input terminal of said flip-flop utilizing a RESET signal received from said RESET input terminal.

11. A system, comprising:
one or more circuits for use in a master-slave flip-flop, said one or more circuits comprising a master circuit, a slave circuit and an input control circuit, and said one or more circuits being operable to:
sense a signal received by said slave circuit from said master circuit at a pair of serially coupled NMOS transistors and/or at a pair of serially coupled PMOS transistors in said slave circuit, wherein:
a gate terminal of a first NMOS transistor in said pair of NMOS transistors is coupled to a terminal at which said signal is received by said slave circuit from said master circuit;
a drain terminal of a second NMOS transistor in said pair of NMOS transistors is coupled to an output terminal of said flip-flop and a gate terminal of said second NMOS transistor is provided with an inverted version of a clock signal;
a gate terminal of a first PMOS transistor in said pair of PMOS transistors is coupled to said terminal at which said signal is received by said slave circuit from said master circuit; and
a drain terminal of a second PMOS transistor in said pair of PMOS transistors is coupled to said output terminal and a gate of said second PMOS transistor is provided with said clock signal; and
generate a corresponding output signal at said output terminal based on said sensing of said signal.

12. The system according to claim 11, wherein a source terminal of said first NMOS transistor is coupled to ground and a source terminal of said first PMOS transistor is coupled to a high voltage.

13. The system according to claim 11, wherein said flip-flop comprises a SET input terminal for generating a high voltage signal at said output terminal.

14. The system according to claim 13, wherein said one or more circuits are operable to:
receive, in a feedback path of said master circuit, an inverted version of a SET signal from said SET input terminal; and
receive, in a feedback path of said slave circuit, said SET signal from said SET input terminal.

15. The system according to claim 13, wherein said one or more circuits are operable to receive, in said master circuit, an inverted version of a SET signal from said SET input terminal via a gate terminal of a third PMOS transistor in said master circuit, wherein:
a drain terminal of said third PMOS transistor is coupled to a terminal between an output of an on-path transmission gate and an input of an on-path inverter in said master circuit; and
a source terminal of said third PMOS transistor is coupled to a high voltage.

16. The system according to claim 13, wherein said one or more circuits are operable to control, in said input control circuit, enabling and disabling of an input terminal of said flip-flop utilizing a SET signal received from said SET input terminal.

17. The system according to claim 11, wherein said flip-flop comprises a RESET input terminal for generating a low voltage signal at said output terminal.

18. The system according to claim 17, wherein said one or more circuits are operable to:
receive, in a feedback path of said master circuit, a RESET signal from said RESET input terminal; and
receive, in a feedback path of said slave circuit, an inverted version of said RESET signal from said RESET input terminal.

19. The system according to claim 17, wherein said one or more circuits are operable to receive, in said master circuit, a RESET signal from said RESET input terminal via a gate terminal of a third NMOS transistor in said master circuit, wherein:
a drain terminal of said third NMOS transistor is coupled to a terminal between an output of an on-path transmission gate and an input of an on-path inverter in said master circuit; and
a source terminal of said third NMOS transistor is coupled to ground.

20. The system according to claim 17, wherein said one or more circuits are operable to control, in said input control circuit, enabling and disabling of an input terminal of said flip-flop utilizing a RESET signal received from said RESET input terminal.
